(19) United States
(12) Patent Application Publication
(10) Pub. No.: US 2026/0344074 A1
(43) Pub. Date: Oct. 29, 2026

(54) SINGLE-PHOTON AVALANCHE DIODE STRUCTURE AND MANUFACTURING PROCESS

(71) Applicant: Taiwan Semiconductor Manufacturing Company, Ltd., Hsinchu (TW)

(72) Inventors: Yin-Kai Liao, Taipei City (TW); Jen-Cheng Liu, Hsin-Chu City (TW); Hsing-Chih Lin, Tainan City (TW); Yi-Shin Chu, Hsinchu City (TW); Hsiang-Lin Chen, Hsinchu County (TW); Sin-Yi Jiang, Hsinchu City (TW); Sung-Wen Huang Chen, Nantou County (TW)

(21) Appl. No.: 19/732,636

(22) Filed: Jul. 7, 2026

Related U.S. Application Data
(63) Continuation of application No. 18/788,220, filed on Jul. 30, 2024.

(51) Int. Cl. H10F 39/00

(52) U.S. Cl. CPC H10F 39/8033; H10F 39/011; H10F 39/8057; H10F 39/8063; H10F 39/811

(57) ABSTRACT

An SPAD with a mesa structure has an etch stop layer that allows a first high-precision etch process that forms substrate contact plugs around the mesa to be combined with a second high-precision etch process that forms a metal grid. The etch stop layer is provided with a first elevation adjacent the substrate contact plugs and a second elevation adjacent the metal grid. The second elevation is greater than the first elevation. In a process, holes for the substrate contact plugs and trenches for the metal grid are etched down to the etch stop layer. After a break-through etch, a third etch process deepens the holes and the trenches to their final depths. The metal grid may land on a second etch stop layer that is absent from an area around the substrate contact plugs. This structure and process provide lower cost SPADs with mesa structures.

### REFERENCE TO RELATED APPLICATION

This Application is a Continuation of U.S. application Ser. No. 18/788,220, filed on Jul. 30, 2024, the contents of which are hereby incorporated by reference in their entirety.

### BACKGROUND

A single-photon avalanche diode (SPAD) is a type of solid-state photodetector that can register single photons for image acquisition, range finding, and other applications. An SPAD includes an absorption region and a multiplication region. The multiplication region comprises a reverse biased p-n junction. Photons absorbed in the absorption region generate electron-hole pairs. The charge carriers are accelerated by the high electric field of the reverse biased p-n junction. The accelerated charge carriers cause impact ionization and an avalanche multiplication process that results in a detectable signal. In Gieger-mode, the p-n junction is reverse biased above a breakdown voltage, which makes the avalanche process self-sustaining. In Gieger-mode, a quench process may be employed to reset the SPAD after a detection event.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1A illustrates a cross-sectional view of a photodetector according to some aspects of the present disclosure.

FIG. 1B illustrates a plan view of the photodetector of FIG. 1A.

FIG. 1C illustrates a wider plan view of the photodetector of FIG. 1A.

FIGS. 2-4 illustrate cross-sectional views of photodetectors according to various embodiments of the present disclosure.

FIGS. 5-22 are a series of cross-sectional views illustrating a process according to some embodiments of the present disclosure.

FIG. 23 provides a cross-sectional view illustrating a variation of the process of FIGS. 5-22.

FIG. 24 provides a flow chart of a process according to some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

The absorption region of an SPAD is provided by a light-sensitive semiconductor. The light-sensitive semiconductor may be selected according to a wavelength of light to be detected and is either embedded in a semiconductor substrate or is provided in the form of a mesa on the semiconductor substrate. The mesa structure has several advantages. One advantage is reduced parasitic capacitance, which leads to faster response times and higher bandwidth. Other advantages include easier passivation and higher fill factor in comparison to an embedded structure.

It is well known, however, that the mesa process has higher fabrication costs. In particular, the mesa is relatively tall, e.g., about 1 μm, so that high precision etching is needed to form structures around the mesa. These have historically included at least a first high-precision etch process to form a light-blocking grid and a second high-precision etch process to form substrate contact plugs. The light-blocking grid comprises segments that block light from travel between adjacent photodetectors pixels so as to reduce crosstalk. The light-blocking grid may be a metal grid having the same composition as the substrate contact plugs but separate etch processes are still used to make trenches for the light-blocking grid and holes for the substrate contact plugs because the light-blocking grid and the substrate contact plugs have different depths. The light-blocking grid lands on a first etch stop layer above the semiconductor substrate. The substrate contact plugs pass through the first etch stop layer and land on the semiconductor substrate.

The present disclosure provides an SPAD structure that includes a first etch stop layer that allows the first high-precision etch process and the second high-precision etch process to be combined into a single etch process that forms both the substrate contact plugs and the light-blocking grid. Both the light-blocking grid and the substrate contact plugs penetrate the first etch stop layer. The first etch stop layer is at a first elevation adjacent the substrate contact plugs and is at a second elevation adjacent the light-blocking grid. The second elevation is greater than the first elevation. In some embodiments, light-blocking grid lands on a second etch stop layer, and this second etch stop layer is absent from the area around the contact plugs.

In a manufacturing process provided by the present disclosure, a mask is formed with first openings for the substrate contact plugs and second openings for the light-blocking grid. A first phase of an etch process using the mask stops on the first etch stop layer so that holes for the substrate contact plugs, which are formed through the first openings, are deeper than the trenches for the light-blocking grid, which are formed through the second openings. A second phase of the etch process breaks through the first etch stop layer. A third phase of the etch process deepens the holes and the trenches. The holes may be deepened until they extend down to or into the semiconductor substrate. The trenches may also be deepened, but they do not reach the semiconductor substrate. In some embodiments, the trenches stop on the second etch stop layer. If the second etch stop layer is employed, the second etch stop layer is absent from the area of the substrate contact plugs so that the second etch stop layer does not interfere with etching the holes. The holes and trenches are filled with metal so that the light-blocking grid and the substrate contact plugs are simultaneously formed.

In some embodiments, the mesa is formed by epitaxial growth of the light-sensitive semiconductor on the semiconductor body. A first oxide layer and the second (lower) etch stop layer are deposited over the semiconductor body and the mesa. An etch process is carried out to pattern the lower etch stop layer. The patterning process selectively removes the lower etch stop layer from the area of the substrate contact plugs. In some embodiments, the first oxide layer is also removed from the area of the substrate contact plugs. A first structure formed from the lower etch stop layer and the first oxide layer remains in the area of the light-blocking grid. A second structure formed from the lower etch stop layer and the first oxide layer may remain around the mesa in the shape of a spacer. A second oxide layer and the first (upper) etch stop layer are then deposited over these structures so that the upper etch stop layer has the first elevation in the area of the substrate contact plugs and the second elevation in the area of the light-blocking grid. In some embodiment, the thicknesses of the first oxide layer and the lower etch stop layer determine the difference between the first elevation and the second elevation. In some embodiments, the upper etch stop layer has a third elevation over the mesa. An interlevel dielectric may be deposited over the upper etch stop layer. The interlevel dielectric may provide a planar upper surface rises at or above the height of the mesa. Masking, etching, and metal deposition may then be used to simultaneously form the light-blocking grid and the substrate contact plugs using just one high precision mask.

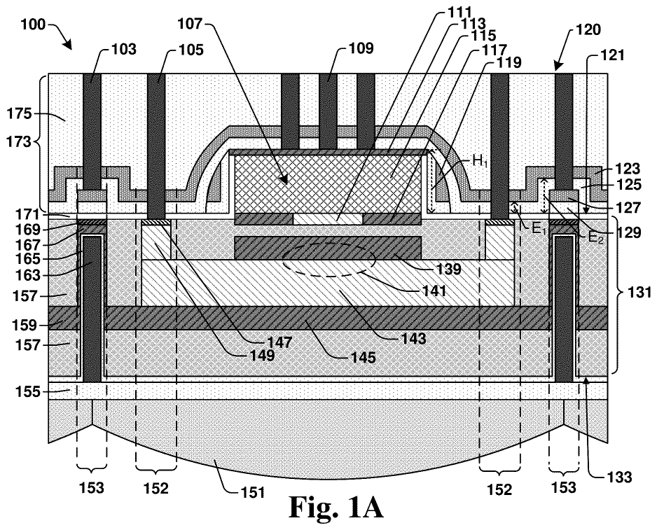

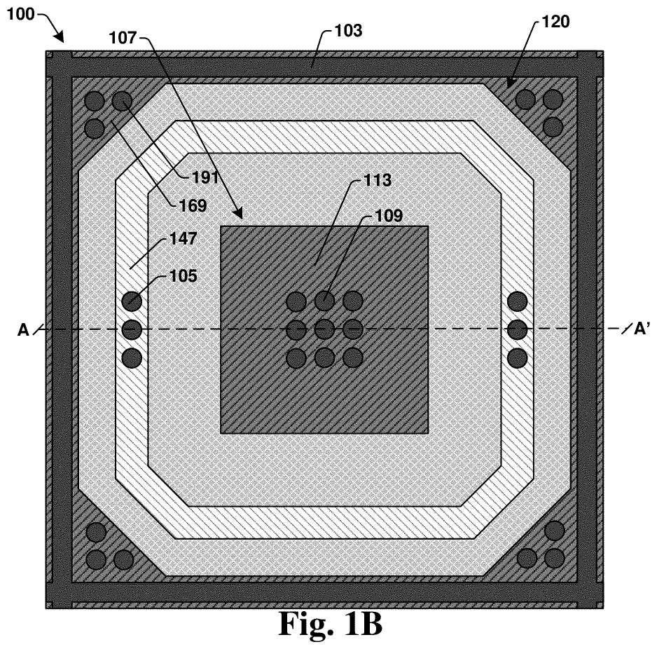

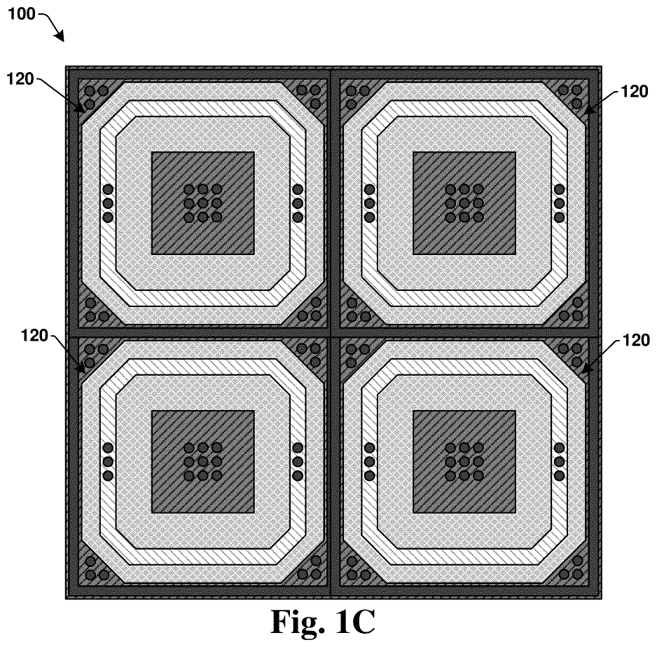

FIG. 1A illustrates a cross-sectional view of a photodetector 100 comprising a photodetector cell 120. The photodetector cell 120 is an SPAD comprising an absorption region 115 and a multiplication region 141. The absorption region 115 is in a mesa 107 on a semiconductor substrate 131. The semiconductor substrate 131 has a front side 121, a back side 133, and includes a semiconductor body 157 having light p-type doping. The multiplication region 141 is formed by an interface between a P-well 139 and an N-well 143 within the semiconductor body 157. Alternatively, a multiplication region may be formed within the mesa 107, or between the mesa 107 and the semiconductor body 157. The absorption region 115 may be formed by a light-sensitive semiconductor having p-type doping. A channel region 111 may be provided by a well having n-type doping directly beneath the mesa 107. The channel region 111 funnels electrons from the absorption region 115. The channel region 111 may be surround by a p-doped region 117, which helps define a width of the channel region 111.

First electrode contact plugs 109 land on the mesa 107. The first electrode contact plugs 109 are coupled to the P-well 139 via the mesa 107, the channel region 111, and the semiconductor body 157. Second electrode contact plugs 105 are coupled to the N-well 143 through a heavily N-doped contact region 147 and N-wells 149. The first electrode contact plugs 109 and the second electrode contact plugs 105 are operative to reverse bias a p-n junction formed between the P-well 139 and the N-well 143 so as to make operative the multiplication region 141. In some embodiments, circuitry (not shown) is connected to the first electrode contact plugs 109 and the second electrode contact plugs 105, and the circuitry is configured to reverse bias the p-n junction above its breakdown voltage. This circuitry may also be configured to provide quenching after a detection event.

The photodetector cell 120 is one element in an array. Electrical isolation between adjacent photodetector cells 120 may be provided by a deep P-well 159, a grid of P-wells 167, and or a back side deep trench isolation (BDTI) structure 163. Optical isolation between adjacent photodetector cells 120 is provided by the BDTI structure 163 and a light-blocking grid 103. The light-blocking grid 103 is aligned to the BDTI structure 163 but is over the front side 121. The photodetector 100 is designed for back side illumination. Microlens 151 may be provided on the back side 133 to help focus incident radiation on absorption regions 115. The BDTI structure 163 and the light-blocking grid 103 increase the efficiency of the photodetector cell 120 while reducing crosstalk.

A dielectric structure 173 is disposed over the semiconductor substrate 131. The dielectric structure 173 comprises a first oxide layer 129, a lower etch stop layer 127, a second oxide layer 125, an upper etch stop layer 123, and an interlevel dielectric 175. An interlevel dielectric is either silicon dioxide (SiO₂), the like, or a low κ dielectric. An etch stop layer is a second type of dielectric having a composition that differs from silicon dioxide (SiO₂) in such a way that provides a much lower etch rate than silicon dioxide in a conventional plasma etching process. Examples of compositions that may be suitable for an etch stop layer include, without limitation, aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like.

The interlevel dielectric 175 fills volume around and over the mesa 107. The mesa 107 has a height H₁ that is much greater than the combined thickness of the first oxide layer 129, the lower etch stop layer 127, the second oxide layer 125, and the upper etch stop layer 123. In some embodiments, the height H₁ in the range from about 0.5 μm to about 10 μm. In some embodiments, the height H₁ is at least about 1 μm. Most of this height is the absorption region 115. The mesa 107 may include a heavily P-doped contact region 113 over the absorption region 115. The heavily P-doped contact region 113 may improve coupling with the first electrode contact plugs 109. The heavily P-doped contact region 113 may be continuous with an intrinsic semiconductor layer 171 that extends over the semiconductor body 157 and up the sides of the mesa 107.

The upper etch stop layer 123 is continuous within each cell of the light-blocking grid 103. The light-blocking grid 103, the first electrode contact plugs 109, and the second electrode contact plugs 105 all pass through and contact the upper etch stop layer 123. The upper etch stop layer 123 has a first elevation E₁ in a first area 152, which is an area where the second electrode contact plugs 105 pass through the upper etch stop layer 123, and has a second elevation E₂ in a second area 153, which is where the light-blocking grid 103 passes through the upper etch stop layer 123. The second area 153 encircles the mesa 107. The first area 152 may encircle the mesa 107 or may be broken up into one or more areas that do not encircle the mesa 107.

The lower etch stop layer 127 is absent from the first area 152, which is around the second electrode contact plugs 105. This causes the lower etch stop layer 127 to be spaced apart from second electrode contact plugs 105. The lower etch stop layer 127 is present in the second area 153, which contains the light-blocking grid 103. A portion of the lower etch stop layer 127 may also be present in a spacer-like structure 119 around the mesa 107. The light-blocking grid 103 lands on the lower etch stop layer 127. The first oxide layer 129 separates lower etch stop layer 127 from the semiconductor substrate 131. The second oxide layer 125 is between the lower etch stop layer 127 and the upper etch stop layer 123. The difference between the first elevation E₁ and the second elevation E₂ may equal the combined thicknesses of the first oxide layer 129 and the lower etch stop layer 127.

In some embodiments, the first oxide layer 129, the lower etch stop layer 127, the second oxide layer 125, and the upper etch stop layer 123 each have thicknesses in the range from about 5 nm to about 200 nm. In some embodiments, the first oxide layer 129, the lower etch stop layer 127, the second oxide layer 125, and the upper etch stop layer 123 each have thicknesses in the range from about 10 nm to about 100 nm. In some embodiments, the first oxide layer 129, the lower etch stop layer 127, the second oxide layer 125, and the upper etch stop layer 123 each have thicknesses in the range from about 15 nm to about 50 nm. In some embodiments, the combined thickness of the first oxide layer 129, the lower etch stop layer 127, the second oxide layer 125, and the upper etch stop layer 123 is 20% or less the height H₁ of the mesa 107. If these layers are too thick in comparison to the height H₁ of the mesa 107, they will not be effective to control etching.

FIG. 1B illustrates a plan view of the photodetector 100. The cross-sectional view of FIG. 1A corresponds to the line A-A′ in FIG. 1B. As shown by FIG. 1B, the heavily N-doped contact region 147 surrounds the mesa 107, as does the light-blocking grid 103. A heavily P-doped contact region 169 may be directly beneath the light-blocking grid 103 and may also occupy additional areas corresponding the corners of the light-blocking grid 103. Third electrode contact plugs 191 connect to the heavily P-doped contact region 169. The first oxide layer 129, the lower etch stop layer 127, the second oxide layer 125, and the upper etch stop layer 123 (see FIG. 1A) may have the same structure around the third electrode contact plugs 191 as they do around the second electrode contact plugs 105 so that the third electrode contact plugs 191 may be formed simultaneously with the second electrode contact plugs 105 and the light-blocking grid 103. The third electrode contact plugs 191 may be used to apply a bias voltage that reduces crosstalk between adjacent photodetector cells 120. FIG. 1C provides a broader plan view showing that the photodetector cells 120 are in an array. The array may contain a very large number of the photodetector cells 120.

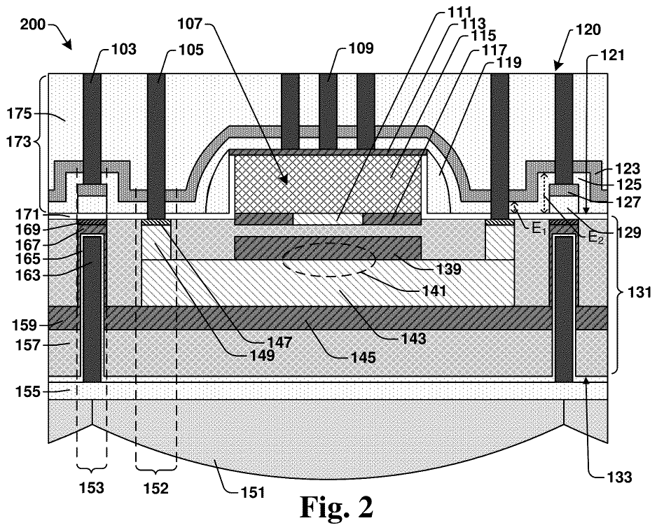

Returning to FIG. 1A, the first elevation E₁ is approximately equal to a thickness of the first oxide layer 129 so that the elevation of the lower etch stop layer 127 in the second area 153 is approximately the same as the elevation of the upper etch stop layer 123 in the first area 152. FIG. 2 illustrates a cross-sectional view of a photodetector 200 which is like the photodetector 100 of FIG. 1 except that in the photodetector 200 the first oxide layer 129 is thicker than the second oxide layer 125. In the photodetector 200, the elevation of the lower etch stop layer 127 in the second area 153 is greater than the elevation of the upper etch stop layer 123 in the first area 152. The photodetector 200 also differs in that the lower etch stop layer 127 is absent from the spacer-like structure 119 (compare FIG. 1), which may be a consequence of the greater thickness of the first oxide layer 129.

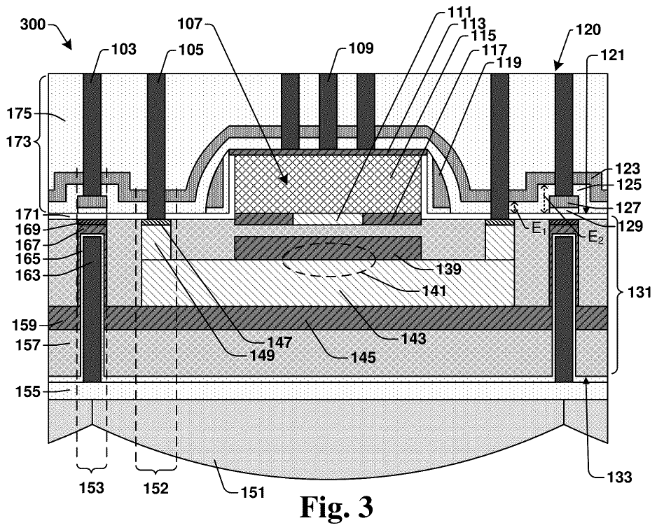

FIG. 3 illustrates a cross-sectional view of a photodetector 300 which is like the photodetector 100 of FIG. 1 except that in the photodetector 300 the first oxide layer 129 is thinner than the second oxide layer 125. In the photodetector 200, the elevation of the lower etch stop layer 127 in the second area 153 is less than the elevation of the upper etch stop layer 123 in the first area 152.

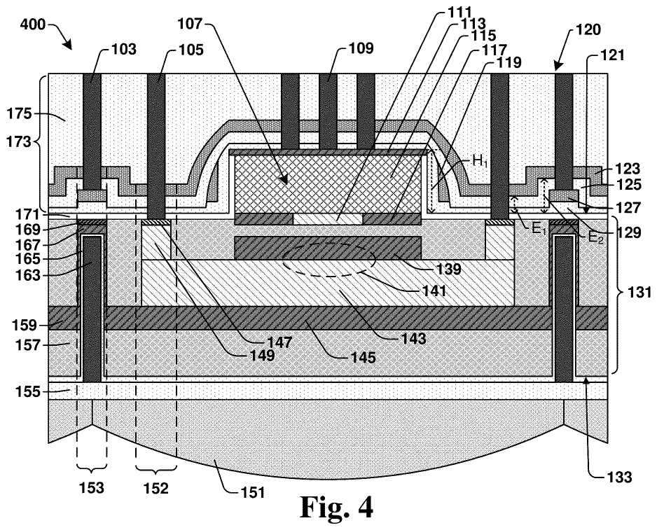

In the photodetectors 100-300 of FIGS. 1-3, the first oxide layer 129 is patterned together with the lower etch stop layer 127. FIG. 4 illustrates a cross-sectional view of a photodetector 400 which differs in that the first oxide layer 129 extends across the photodetector cell 120 so that at least a portion of the thickness of the first oxide layer 129 is between the second oxide layer 125 and the substrate in the first area 152 so that the first oxide layer 129 contributes to the elevation E₁ of the upper etch stop layer 123 in the first area 152.

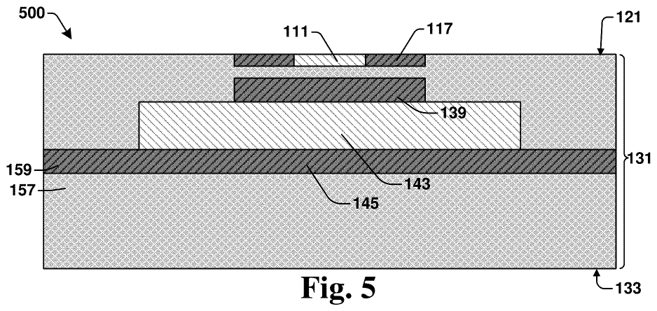

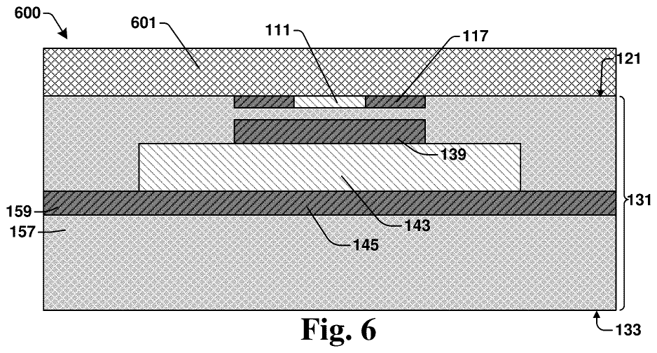

FIGS. 5-22 provide a series of cross-sectional views 500-2200 that illustrate an integrated circuit device according to the present disclosure at various stages of manufacture according to a process of the present disclosure. Although FIGS. 5-22 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 5-22 are described in relation to a series of acts, it will be appreciated that the structures shown in FIGS. 5-22 are not limited to a method of manufacture but rather may stand alone as structures separate from the method.

As shown by the cross-sectional view 500 of FIG. 5, the method may begin with a series of masking and doping operations that form the deep P-well 145, the N-well 143, the P-well 139, the channel region 111, and the p-doped region 117 in the semiconductor body 157 of the semiconductor substrate 131. The semiconductor substrate 131 may be any type of substrate that comprises the semiconductor body 157. The semiconductor body 157 may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, the semiconductor body 157 is silicon (Si) or the like.

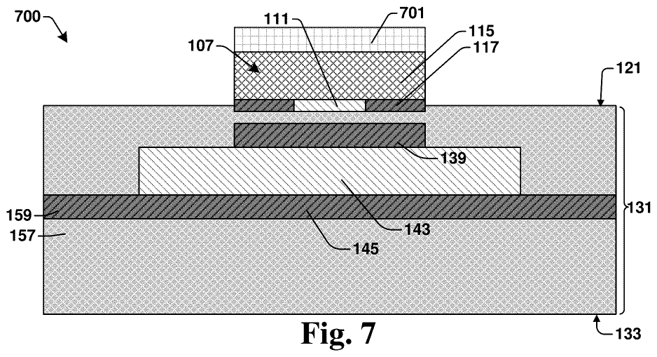

As shown by the cross-sectional view 600 of FIG. 6, a semiconductor 601 is epitaxially grown on the semiconductor body 157. In some embodiments, the semiconductor 601 is a distinct semiconductor material from the semiconductor body 157. The semiconductor 601 provides the absorption region for an SPAD and may be selected accordingly. In some embodiments, the semiconductor 601 is germanium (Ge). SPADs using germanium (Ge) for light absorption are sensitive to near infrared (NIR) light and have applications such as detecting signals from fiber optic networks, light detection and ranging (Lidar) systems, quantum cryptography, astronomy, and the like. Other semiconductors that may be suitable for the semiconductor 601 depending on the application include, without limitation, silicon (Si), aluminum gallium arsenide (AlGaAs), indium gallium arsenide (InGaAS), indium phosphide (InP), gallium nitride (GaN), silicon carbide (SiC), mercury cadmium telluride (HgCdTe), and the like.

As shown by the cross-sectional view 700 of FIG. 7, a mask 701 is formed and an etch process is carried out to etch the mesa 107 from the semiconductor 601. A remaining portion of the semiconductor 601 provides the absorption region 115. The mask 701 and other masks used in processes of this disclosure may be or comprise a photoresist, a hard mask, or the like. The mask 701 and other masks used in this process may be patterned by photolithography, ion beam lithography, the like, or some other suitable process. The etch process may be a dry etch such as a plasma etch, the like, or some other suitable etch process. After the etch process, the mask 701 may be stripped. Etching may recess the front side 121 below a height of the channel region 111 and the p-doped region 117 beneath the mesa 107.

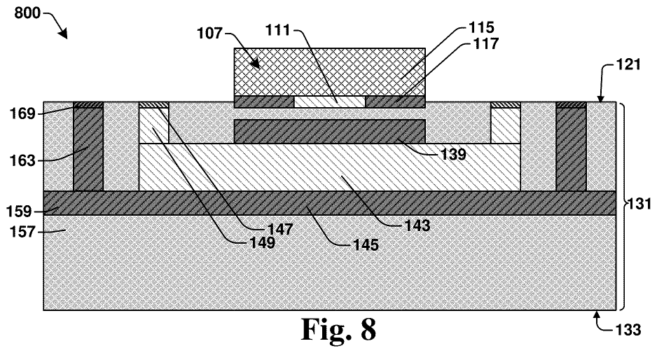

As shown by the cross-sectional view 800 of FIG. 8, additional masking and doping operations may be carried out to form the P-wells 167, the heavily P-doped contact regions 169, the N-wells 149, and the heavily N-doped contact regions 147. The plan view of FIG. 1B illustrates a possible layout for these regions.

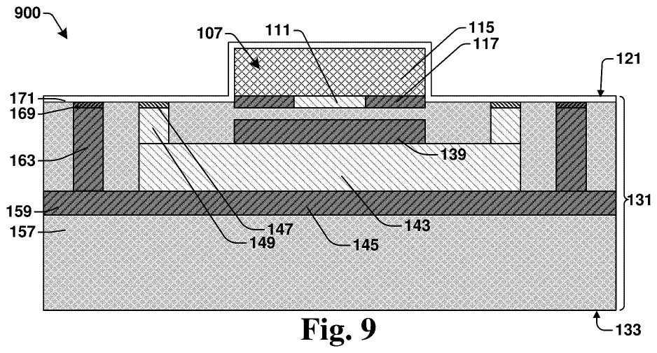

As shown by the cross-sectional view 900 of FIG. 9, the intrinsic semiconductor layer 171 may be epitaxially grown over the structure shown by the cross-sectional view 800 of FIG. 8. The intrinsic semiconductor layer 171 may provide passivation. In some embodiments, the intrinsic semiconductor layer 171 is a distinct semiconductor material from the absorption region 115. In some embodiments, the intrinsic semiconductor layer 171 comprises the same semiconductor material as the semiconductor body 157.

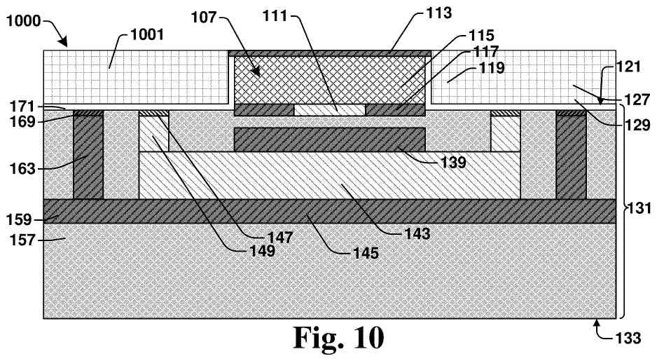

As shown by the cross-sectional view 1000 of FIG. 10, a mask 1001 may be formed and used while the intrinsic semiconductor layer 171 is selectively doped in the area over the mesa 107 to form the heavily P-doped contact region 113. After doping, the mask 1001 may be stripped.

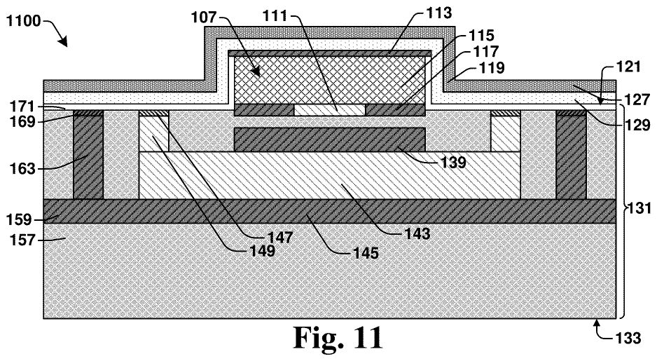

As shown by the cross-sectional view 1100 of FIG. 11, the first oxide layer 129 and the lower etch stop layer 127 may be deposited over the structure shown by the cross-sectional view 1000 of FIG. 10. The first oxide layer 129 may be silicon dioxide (SiO₂), the like, or any other suitable dielectric. The lower etch stop layer 127 may include one or more layers of aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like. In some embodiments, the lower etch stop layer 127 is or comprises silicon nitride (SiN). The first oxide layer 129 and the lower etch stop layer 127 may be deposited by chemical vapor deposition (CVD), physical vapor deposition (PVD), atomic layer deposition (ALD), the like, or any other suitable process(es). Alternatively, the first oxide layer 129 may be formed by oxidation.

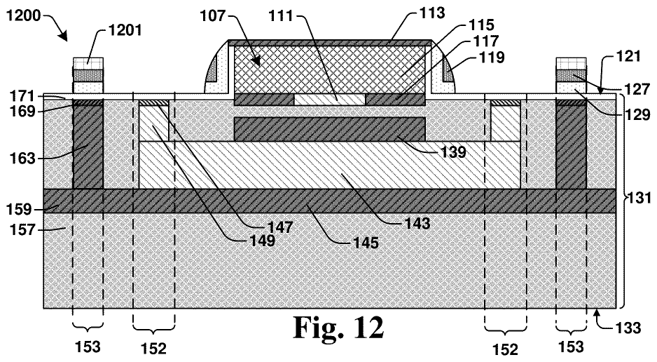

As shown by the cross-sectional view 1200 of FIG. 12, a mask 1201 may be formed over the second areas 153 and an etch process carried out to remove the first oxide layer 129 and the lower etch stop layer 127 from the first areas 152 and other areas. The etch process may be a plasma etch or other directional etching process that leaves portions of the first oxide layer 129 and or the lower etch stop layer 127 in spacer-like structures 119 around the mesas 107. After etching, the mask 1201 may be stripped.

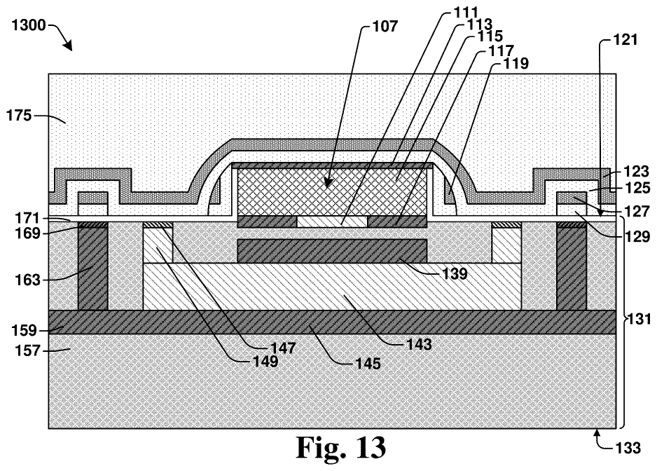

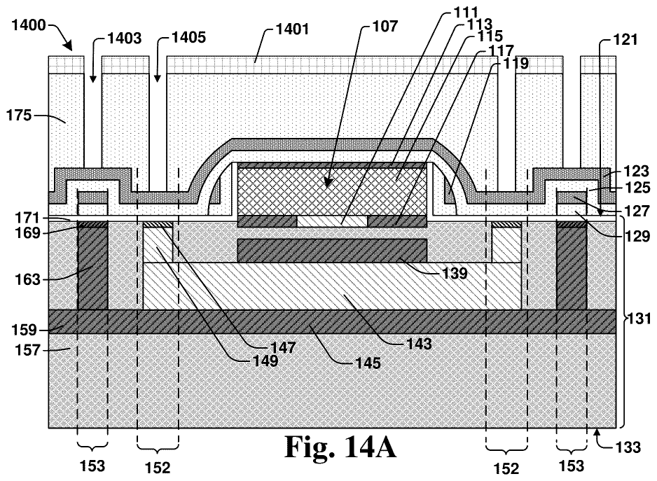

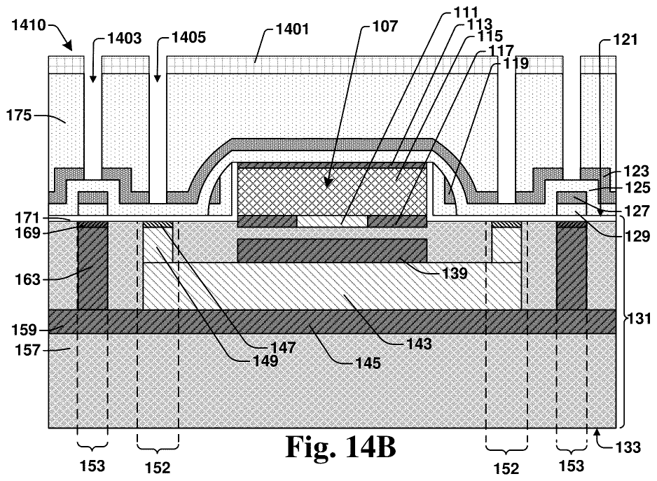

As shown by the cross-sectional view 1300 of FIG. 13, the second oxide layer 125, the upper etch stop layer 123, and the interlevel dielectric 175 may be deposited over the structure shown by the cross-sectional view 1200 of FIG. 12. The second oxide layer 125 may be silicon dioxide (SiO₂), the like, or any other suitable dielectric. The upper etch stop layer 123 may include one or more layers of aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like. In some embodiments, the upper etch stop layer 123 is or comprises silicon nitride (SiN). The interlevel dielectric 175 may include one or more layers of silicon dioxide (SiO₂), a low-κ interlevel dielectric, or an extremely low-κ dielectric. A low-κ dielectric is one having a smaller dielectric constant than silicon dioxide (SiO₂). Examples of low-κ dielectrics include organosilicate glasses (OSG) such as carbon-doped silicon dioxide, fluorine-doped silicon dioxide otherwise referred to as fluorinated silica glass (FSG), organic polymer low-κ dielectrics, and porous silicate glass. An extremely low-κ dielectric material is generally a low-κ dielectric material formed into a porous structure. Porosity reduces the effective dielectric constant. The second oxide layer 125, the upper etch stop layer 123, and the interlevel dielectric 175 may be deposited by ALD, CVD, PVD, the like, or any other suitable process(es). A planarization process may be used to provide the interlevel dielectric 175 with a planar upper surface. The planarization process may be chemical mechanical polishing (CMP), the like, or any other suitable process.

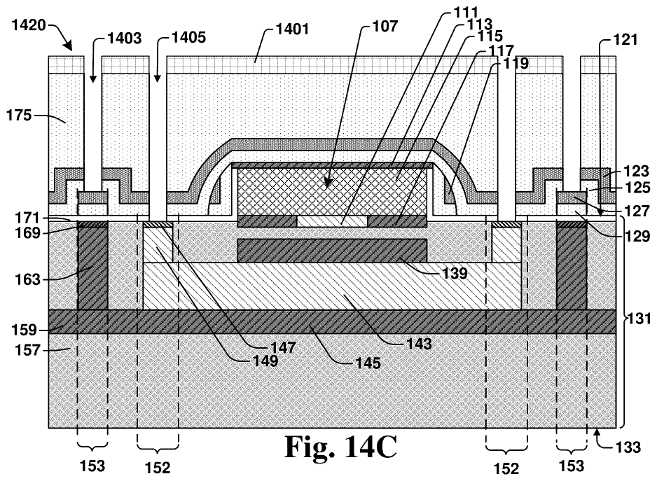

As shown by the cross-sectional view 1400, 1410, and 1420 of FIGS. 14A-14C, a high precision mask 1401 may be formed and used to etch second electrode contact holes 1405 in the first areas 152 and trenches 1403 in the second areas 153. The etch process may include three stages. As shown by the cross-sectional view 1400 of FIG. 14A the first stage, which is carried out with a first etch condition, forms the second electrode contact holes 1405 and the trenches 1403 to the depth of the upper etch stop layer 123. As shown by the cross-sectional view 1410 of FIG. 14B, the second stage, which is carried out with a second etch condition, breaks through the upper etch stop layer 123 in the second electrode contact holes 1405 and the trenches 1403. As shown by the cross-sectional view 1420 of FIG. 14C, the third stage, which is carried out with a third etch condition (and may be the same as or different from the first etch condition), deepens the second electrode contact holes 1405 and the trenches 1403. The second electrode contact holes 1405 are deepened until they reach the heavily N-doped contact regions 147 within the semiconductor body 157. The trenches 1403 are deepened to the lower etch stop layer 127. The lower etch stop layer 127 may prevent the trenches 1403 from deepening further. The thickness of the first oxide layer 129, the second oxide layer 125, and the lower etch stop layer 127 are selected to facilitate this processing.

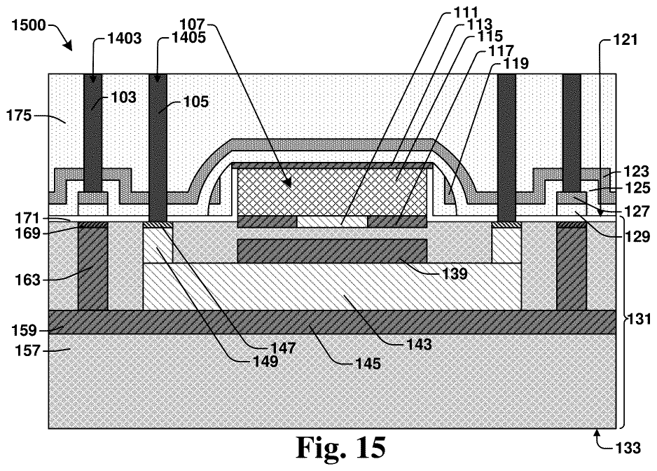

As shown by the cross-sectional view 1500 of FIG. 15, the second electrode contact holes 1405 and the trenches 1403 are filled with metal to form second electrode contact plugs 105 and the light-blocking grid 103. The metal may be deposited by PVD, CVD, ALD, electroplating, electroless plating, the like, or other suitable process so as to fill the holes 1405 and the trenches 1403 followed by planarization to remove excess metal. The planarization process may be CMP or the like. The metal may be or comprise tungsten (W), aluminum (Al), copper (Cu), cobalt (Co), cobalt silicide (CoSi₂), nickel (Ni), nickel silicide (NiSi), an alloy thereof, or the like.

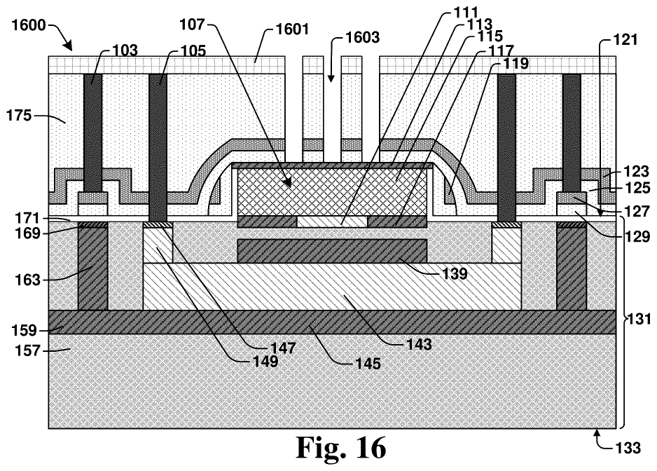

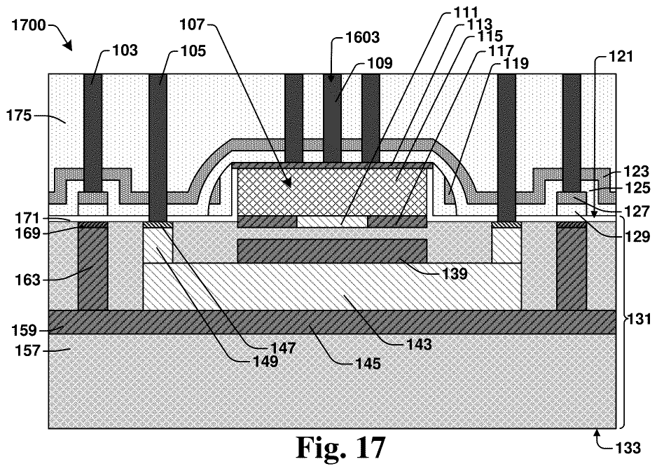

As shown by the cross-sectional view 1600 of FIG. 16, a mask 1601 may be formed and used to etch first electrode contact holes 1603 over the mesas 107. As shown by the cross-sectional view 1700 of FIG. 17, the first electrode contact holes 1603 are filled with metal to form first electrode contact plugs 109. The metal may be deposited by PVD, CVD, ALD, electroplating, electroless plating, the like, or other suitable process so as to fill the holes 1603 followed by planarization to remove excess metal. The planarization process may be CMP or the like. The metal may be or comprise tungsten (W), aluminum (Al), copper (Cu), cobalt (Co), cobalt silicide (CoSi₂), nickel (Ni), nickel silicide (NiSi), an alloy thereof, or the like.

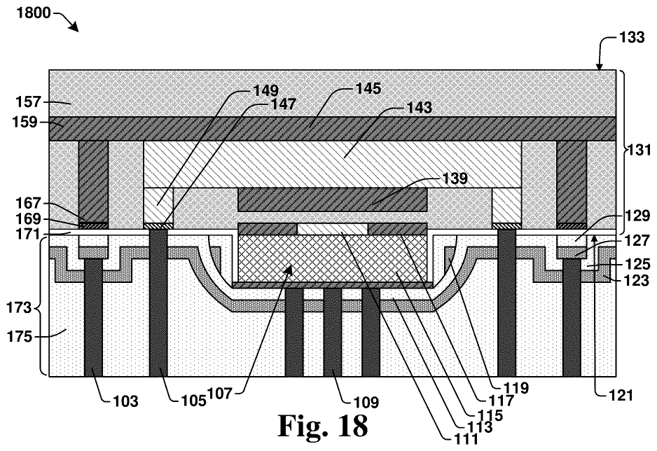

As shown by the cross-sectional view 1800 of FIG. 18, the semiconductor substrate 131 may be thinned from the back side 133. The thinning process may comprise grinding, polishing, the like, or any other suitable process or processes. The semiconductor substrate 131 may be bonded to a second substrate (not shown) prior to the thinning process.

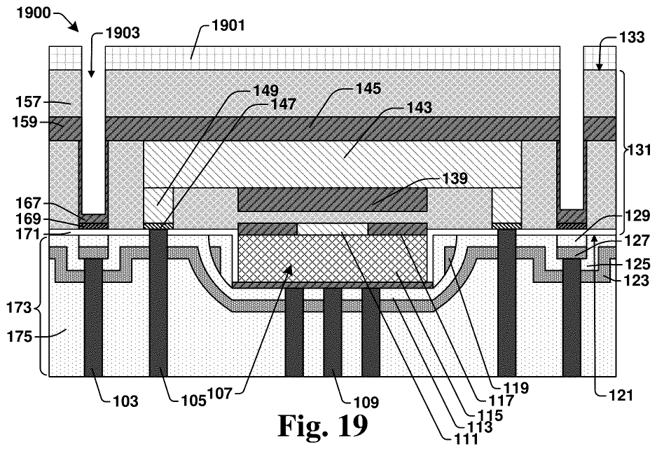

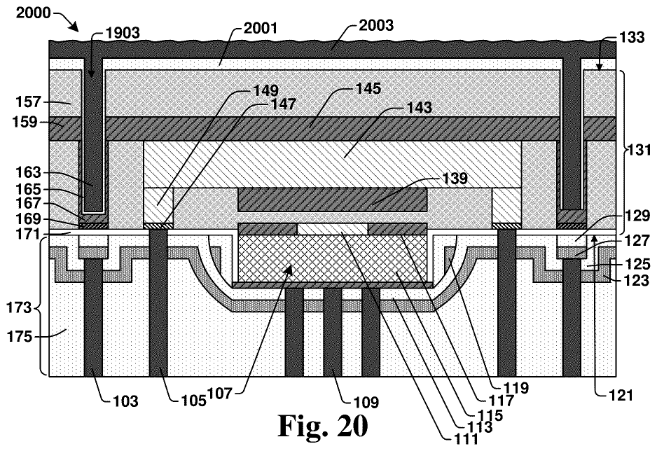

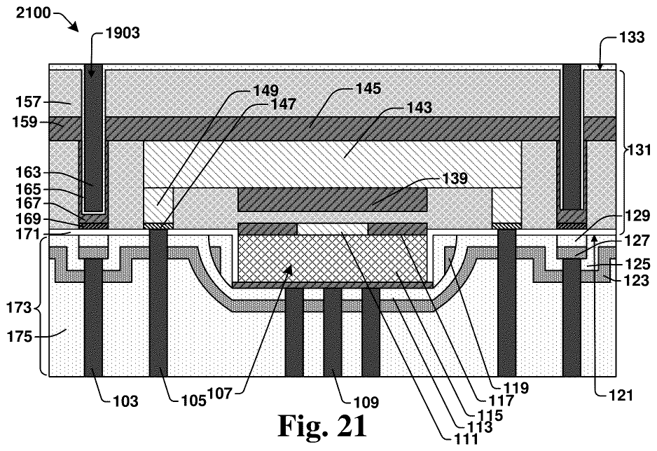

As shown by the cross-sectional view 1900 of FIG. 19, a mask 1901 may be formed and used to etch trenches 1903 in the back side 133. The trenches 1903 may be aligned to the light-blocking grid 103 on the front side 121 and may extend into the P-wells 167. As shown by the cross-sectional view 2000 of FIG. 20, a dielectric layer 2001 and a metal layer 2003 may be deposited so as to fill the trenches 1903. The dielectric layer 2001 may comprises one or more dielectric layers. In some embodiments, the dielectric layer 2001 includes a high-κ dielectric layer. The high-κ dielectric layer may be hafnium oxide (HfO), aluminum oxide (AlO), zirconium oxide (ZrO), titanium oxide (TiO), strontium oxide (SrO), barium oxide (BaO), barium titanate (BaTiO₃), tantalum oxide (Ta₂O₃), lanthanum oxide (La₂O₃), yttrium oxide (Y₂O₃), a mixture thereof, or the like. The metal layer 2003 may be aluminum (Al), tungsten (W), the like, or any other suitable metal. As shown by the cross-sectional view 2100 of FIG. 21 a planarization process such as CMP or the like may be carried out to remove excess metal from the back side 133. The remaining portions of the metal layer 2003 forms the BDTI structure 163. The dielectric layer 2001 forms an insulating layer 165 that lines the BDTI structure 163. The planarization process may leave a portion of the insulating layer 165 on the back side 133 to provide a passivation layer.

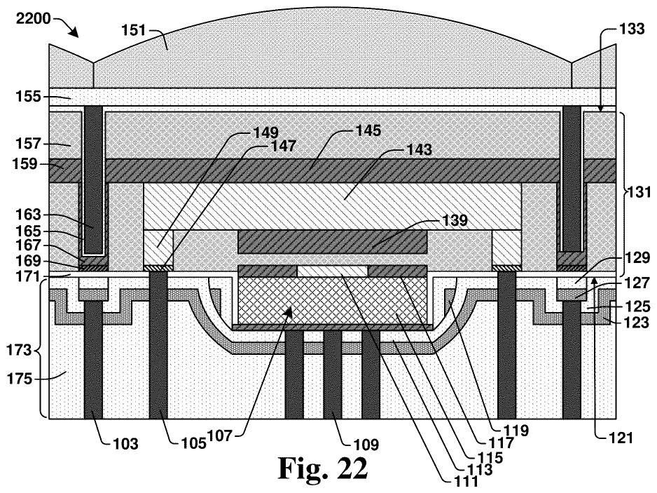

As shown by the cross-sectional view 2200 of FIG. 22, additional structures may be formed on the back side 133. These may include a passivation layer 155 and microlenses 151.

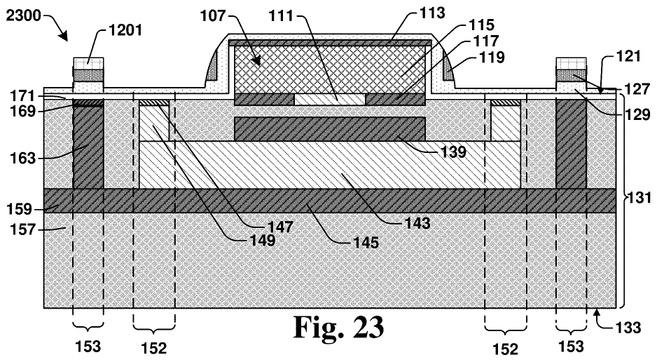

FIG. 23 provides a cross-sectional view 2300 illustrating a variation on the process of FIGS. 5-22. The variation relates specifically to the process illustrated by the cross-sectional view 1200 of FIG. 12. As shown by the cross-sectional view 2300 of FIG. 23 the etch process that patterns the lower etch stop layer 127 may be selective and etching of the first oxide layer 129 limited whereby all or part of the original thickness of the first oxide layer 129 remains in the first areas 152 and other unmasked areas. The processing may then continue as shown in FIGS. 13-22.

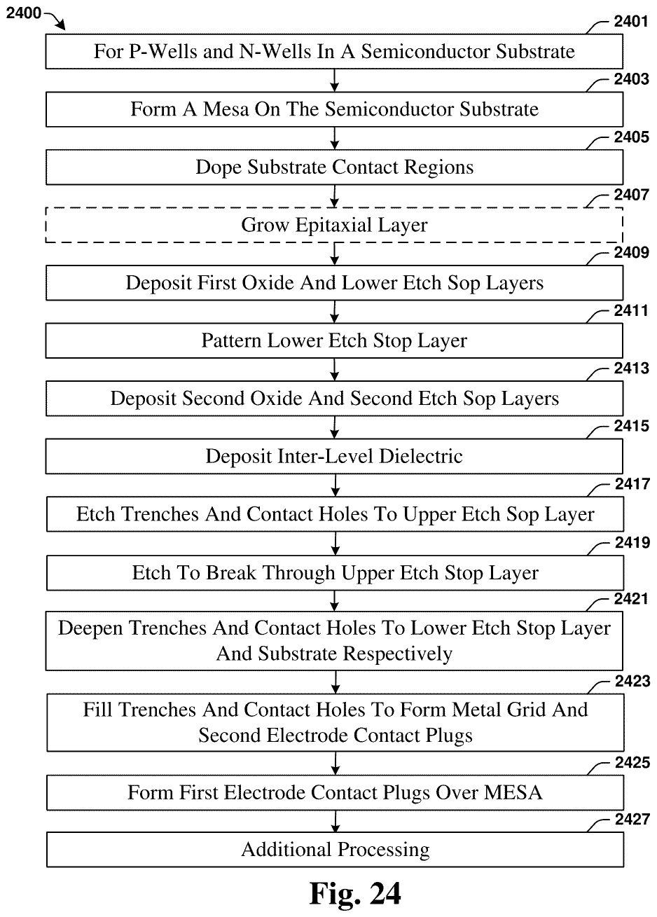

FIG. 24 provides a flow diagram for a method 2400 of forming photodetector according to some embodiments. While the method 2400 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2400 may begin with act 2401, doping a semiconductor substrate to form various wells associated with an SPAD structure. These may include wells that provide isolation, wells that provide multiplication regions, and wells that channel charge carriers from the absorption region to the multiplication region. The cross-sectional view 500 of FIG. 5 provides an example.

Act 2403 is forming a mesa on the semiconductor substrate. In some embodiments, forming the mesa include epitaxially growing a second semiconductor on the semiconductor substrate followed by etching to define the shape of the mesa. The cross-sectional views 600-700 of FIGS. 6 and 7 provide an example.

Act 2405 is doping to form substrate contact regions in the semiconductor substrate lateral to the mesa. The cross-sectional view 800 of FIG. 8 provides an example.

Act 2407 is an optional step of epitaxially growing a layer of intrinsic semiconductor on the mesa and on the surface of the semiconductor substrate. The layer of intrinsic semiconductor may be doped on top of the mesa to provide a contact region. The cross-sectional views 900-1000 of FIGS. 9-10 provide an example.

Act 2409 is forming a first oxide layer and a lower etch stop layer over the mesa and the surface of the semiconductor substrate. The first oxide layer contributes to spacing and provides separation between the lower etch stop layer and the semiconductor substrate but may be considered optional. The cross-sectional view 1100 of FIG. 11 provides an example.

Act 2411 is patterning the lower etch stop layer. Patterning removes the lower etch stop layer from an area where substrate contact plugs are desired and leaves the lower etch stop layer in an area where a light-blocking grid is to be formed. The cross-sectional view 1200 of FIG. 12 provides a first example in which the first oxide layer is patterned together with the lower etch stop layer. The cross-sectional view 2300 of FIG. 23 provides a second example in which the patterning process does not etch through the first oxide layer. Patterning may leave a spacer-like structure around the mesa due to the directional nature of the etching process. Depending on the thickness of the first oxide layer, this spacer-like structure may contain some of the lower etch stop layer.

Act 2413 is depositing a second oxide layer and an upper etch stop layer over the mesa, over the first etch stop layer, and over the surface of the semiconductor substrate. Act 2415 is depositing an interlevel dielectric layer that may be planarized to a surface above the height of the mesa. The cross-sectional view 1300 of FIG. 13 provides an example.

Act 2417 is a first step in a process of simultaneously etching holes for substrate contact plugs and trenches for a light-blocking grid. This first step forms holes and trenches that land on the upper etch stop layer. The cross-sectional view 1400 of FIG. 14A provides an example. Act 2419 is a second step in the etch process. This second step breaks through the upper etch stop layer. The cross-sectional view 1410 of FIG. 14B provides an example. Act 2421 is a third step in the etch process. This third step deepens the holes and trenches. The holes are deepened at least down to the surface of the semiconductor substrate. The trenches are deepened to the lower etch stop layer. The cross-sectional view 1420 of FIG. 14C provides an example. Act 2423 is filling the holes and trenches with metal to form substrate contact plugs and a light-blocking grid. The cross-sectional view 1500 of FIG. 15 provides an example.

Act 2425 is forming electrode contact plugs over the mesa. The cross-sectional views 1600-1700 of FIGS. 16-17 provides an example. Act 2427 is additional processing that completes formation of a photodetector with SPADs. This may include binding the semiconductor substrate to a second substrate, thinning the semiconductor substrate from the back side, forming a BDTI structure, and forming microlenses on the back side. The cross-sectional views 1800-2200 of FIGS. 18-22 provide an example.

Some aspects of the present disclosure relate to a photodetector that includes a semiconductor substrate, a mesa on the semiconductor substrate, and a single photon avalanche diode (SPAD) having an absorption region in the mesa. A first electrode contact plug for the SPAD lands on top of the mesa. A second electrode contact plug for the SPAD lands on the semiconductor substrate to one side of the mesa. The mesa is within a cell of a light-blocking grid over the front side of the substrate. Both the light-blocking grid and the second electrode contact plug pass through an upper etch stop layer. An elevation of the upper etch stop layer is variable so that the upper etch stop layer has a first elevation where the second electrode contact plug passes through the upper etch stop layer and a second elevation where the light-blocking grid passes through the upper etch stop layer.

In some embodiments, the photodetector further include a first oxide layer, a lower etch stop layer, and a second oxide layer. The first oxide layer is between the lower etch stop layer and the upper etch stop layer. The second oxide layer is between the lower etch stop layer and the semiconductor substrate. The lower etch stop layer is spaced apart from the second electrode contact plug. In some embodiments, a difference between the second elevation and the first elevation equals a combined thickness of the second oxide layer and the lower etch stop layer. In some embodiments, the light-blocking grid lands on the lower etch stop layer. In some embodiments, there is a sidewall spacer around the mesa. A first part of the sidewall spacer has a composition of the first oxide layer and a second portion of the sidewall spacer has a composition of the lower etch stop layer. In some embodiments, the lower etch stop layer and the upper etch stop layer comprise silicon nitride, and the first oxide layer and the second oxide layer comprise silicon dioxide. In some embodiments, the first electrode contact plug passes through the upper etch stop layer above the mesa. In some embodiments, the upper etch stop layer has a lower elevation over the semiconductor substrate than any other etch stop layer that contacts the second electrode contact plug.

In some embodiments, the photodetector further comprises a third contact plug. The third contact plug contacts a first heavily doped region of the semiconductor substrate, the second electrode contact plug contacts a second heavily doped region of the semiconductor substrate, and the first heavily doped region and the second heavily doped region have opposite doping types. In some embodiments, the photodetector further comprises a back side metal grid that is within the semiconductor substrate and is aligned to the light-blocking grid. In some embodiments, the semiconductor substrate and the absorption region are different semiconductor materials. In some embodiments, the photodetector further comprises a layer of intrinsic silicon at an upper surface of the semiconductor substrate, wherein the second electrode contact plug extends through the layer of intrinsic silicon. In some embodiments, the first electrode contact plug is an anode terminal, the second electrode contact plug is a cathode terminal, and the mesa comprises germanium. In some embodiments, the photodetector further comprises a multiplication region and a channel region for the single photon avalanche diode. The multiplication region comprises a PN junction in the semiconductor substrate below the mesa, and the PN junction is formed by a first p-doped region over a first n-doped region. The channel region is a second n-doped region of the semiconductor substrate below the mesa and between the mesa and the multiplication region. In some embodiments, a second p-doped region of the semiconductor substrate is directly beneath the mesa and surrounds the second n-doped region.

Some aspects of the present disclosure relate to a photodetector that includes a semiconductor substrate, a mesa on the semiconductor substrate, a diode comprising an absorption region in the mesa, a first electrode contact plug for the diode, wherein the first electrode contact plug lands on top of the mesa, a second electrode contact plug for the diode, wherein the second electrode contact plug passes through a number of etch stop layers and lands on the semiconductor substrate to one side of the mesa, and a light-blocking grid over the semiconductor substrate, wherein the light-blocking grid passes through an equal number of etch stop layers as the second electrode contact plug and lands on an additional etch stop layer. The mesa is within an area corresponding to a cell of the light-blocking grid.

Some aspects of the present disclosure relate to a method of manufacturing a photodetector. The method includes providing a semiconductor body, forming a p-n junction in the semiconductor body, epitaxially growing a second semiconductor on the front side of the semiconductor body, patterning the second semiconductor to form a mesa of the second semiconductor over the p-n junction, doping the semiconductor body in an area to one side of the mesa to form a first contact region in the semiconductor body, depositing a first oxide layer, depositing a lower etch stop layer over the first oxide layer, pattering the lower etch stop layer, wherein patterning removes the lower etch stop layer from an area over the first contact region, depositing a second oxide layer, depositing an upper etch stop layer over the second oxide layer, forming an interlevel dielectric layer over the upper etch stop layer, forming a mask over the interlevel dielectric layer, wherein the mask has a first opening over the first contact region and second opening that form a grid, etching through the mask, wherein etching forms a first hole corresponding to the first opening and trenches corresponding to the second opening, and depositing metal, wherein the metal fills the first hole to form a first electrode contact plug and fills the trenches to form a light-blocking grid, wherein the light-blocking grid is spaced over semiconductor body and the first electrode contact plug is in or on the semiconductor body and is coupled to the first contact region.

In some embodiments, the light-blocking grid is above the lower etch stop layer. In some embodiments, etching through the mask includes applying a first etch process that stops on the upper etch stop layer, applying a second etch process that breaks through the upper etch stop layer, and applying a third etch process, wherein the third etch process stops on or in the semiconductor body in the first openings and stops on the lower etch stop layer in the second openings. In some embodiments, the method further includes growing an epitaxial layer of the light-sensitive semiconductor over the front side, wherein the first hole extends through the epitaxial layer. In some embodiments, pattering the lower etch stop layer leaves a portion of the lower etch stop layer in the form of a spacer around the mesa.

In some embodiments, the method further includes forming a second mask over the interlevel dielectric layer, wherein the second mask has a third opening over the mesa, etching through the second mask, wherein etching forms a second hole corresponding to the third opening, and depositing more metal, wherein the more metal fills the second hole to form a second electrode contact plug, wherein the second electrode contact plug is coupled through the mesa to the PN junction. In some embodiments, the method further includes doping second areas of the semiconductor body. The second areas comprise a well surrounding the mesa and the first contact region, and the well has an opposite doping type from the first contact region. In some embodiments, the well include a grid-shaped area corresponding to the light-blocking grid. In some embodiments, the method further includes doping to form a second contact region which is a contact region for the well. In these embodiments, the mask has a third opening, etching through the mask forms a second hole corresponding to the third opening, and depositing metal forms a second electrode contact plug in the second hole, and the second electrode contact plug couples to the second contact region. In some embodiments, the method further includes thinning the semiconductor body from the back side and forming a back side metal grid. In some embodiments, the back side metal grid has the same layout as the light-blocking grid. In some embodiments, the method further includes forming a microlens on the back side.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photodetector, comprising:
a semiconductor substrate;
a mesa on the semiconductor substrate;
a single photon avalanche diode comprising an absorption region in the mesa;
an upper etch stop layer;
a first electrode contact plug for the single photon avalanche diode, wherein the first electrode contact plug lands on top of the mesa;
a second electrode contact plug for the single photon avalanche diode, wherein the second electrode contact plug passes through the upper etch stop layer, and lands on the semiconductor substrate to one side of the mesa; and
a light-blocking grid over the semiconductor substrate, wherein the light-blocking grid passes through the upper etch stop layer;
wherein the upper etch stop layer has a first elevation at a first location when the second electrode contact plug passes through the upper etch stop layer, the upper etch stop layer has a second elevation at a second location when the light-blocking grid passes through the upper etch stop layer, and the second elevation is distinct from the first elevation.

2. The photodetector of claim 1, further comprising:
a lower etch stop layer, wherein the light-blocking grid lands on the lower etch stop layer;
a first oxide layer, wherein the first oxide layer is between the lower etch stop layer and the semiconductor substrate; and
a second oxide layer, wherein the second oxide layer is between the lower etch stop layer and the upper etch stop layer.

3. The photodetector of claim 2, wherein a difference between the second elevation and the first elevation equals a combined thickness of the second oxide layer and the lower etch stop layer.

4. The photodetector of claim 2, wherein the lower etch stop layer is spaced apart from the second electrode contact plug.

5. The photodetector of claim 2, further comprising a sidewall spacer around the mesa, wherein a first part of the sidewall spacer has a composition of the first oxide layer and a second portion of the sidewall spacer has a composition of the lower etch stop layer.

6. The photodetector of claim 1, wherein the first electrode contact plug passes through the upper etch stop layer above the mesa.

7. The photodetector of claim 6, wherein the upper etch stop layer has a lower elevation over the semiconductor substrate than any other etch stop layer that contacts the second electrode contact plug.

8. The photodetector of claim 1, further comprising a third contact plug, wherein the third contact plug contacts a first heavily doped contact region of the semiconductor substrate, the second electrode contact plug contacts a second heavily doped contact region of the semiconductor substrate, and the first heavily doped contact region and the second heavily doped contact region have opposite doping types.

9. The photodetector of claim 1, further comprising a back side metal grid that is within the semiconductor substrate and is aligned to the light-blocking grid.

10. The photodetector of claim 1, wherein:
the semiconductor substrate comprises a semiconductor body; and
the semiconductor body and the absorption region comprises different semiconductor materials.

11. The photodetector of claim 1, further comprising a layer of intrinsic semiconductor at an upper surface of the semiconductor substrate, wherein the second electrode contact plug extends through the layer of intrinsic semiconductor.

12. The photodetector of claim 1, further comprising:
a multiplication region for the single photon avalanche diode, wherein the multiplication region comprises a PN junction in the semiconductor substrate below the mesa, and the PN junction is formed by a first p-doped region over a first n-doped region; and
a channel region for the single photon avalanche diode, wherein the channel region is a second n-doped region of the semiconductor substrate below the mesa and between the mesa and the multiplication region.

13. The photodetector of claim 12, wherein a second p-doped region of the semiconductor substrate is directly beneath the mesa and surrounds the second n-doped region.

14. A photodetector, comprising:
a semiconductor substrate;
a mesa on the semiconductor substrate;
a diode having an absorption region in the mesa;
a first electrode contact plug for the diode, wherein the first electrode contact plug lands on top of the mesa;
a second electrode contact plug for the diode, wherein the second electrode contact plug passes through a dielectric structure and lands on the semiconductor substrate to one side of the mesa, wherein the dielectric structure comprises an interlevel dielectric, which is silicon dioxide (SiO₂) or a low k dielectric, and a plurality of second-type dielectric layers, which each comprise one or another of aluminum oxide (AlOx), silicon nitride (SiN), silicon carbide (SiC), silicon carbonitride (SiCN), silicon oxycarbide (SIOC), or silicon oxycarbonitiride (SiOCN); and
a light-blocking grid over the semiconductor substrate, wherein the light-blocking grid passes through the plurality of second-type dielectric layers and lands on another second-type dielectric layer which comprises one of aluminum oxide (AlOx), silicon nitride (SiN), silicon carbide (SiC), silicon carbonitride (SiCN), silicon oxycarbide (SIOC), or silicon oxycarbonitiride (SiOCN).

15. A method of manufacturing a photodetector, the method comprising:
providing a semiconductor body having a front side and a back side;
forming a p-n junction in the semiconductor body;
epitaxially growing a second semiconductor on the front side of the semiconductor body;
patterning the second semiconductor, wherein patterning leaves a mesa comprising the second semiconductor over the p-n junction;
doping the semiconductor body in an area to one side of the mesa, wherein doping forms a first contact region in the semiconductor body;
depositing a first oxide layer;
depositing a lower etch stop layer over the first oxide layer;
pattering the lower etch stop layer, wherein patterning removes the lower etch stop layer from an area over the first contact region;
depositing a second oxide layer;
depositing an upper etch stop layer over the second oxide layer;
forming an interlevel dielectric layer over the upper etch stop layer;
forming a mask over the interlevel dielectric layer, wherein the mask has a first opening over the first contact region and a second opening in the shape of a grid;
etching through the mask, wherein etching forms a first hole corresponding to the first opening and trenches corresponding to the second opening; and
depositing metal, wherein the metal fills the first hole to form a first electrode contact plug and fills the trenches to form a light-blocking grid, wherein the light-blocking grid is spaced over semiconductor body and the first electrode contact plug is in or on the semiconductor body and is coupled to the first contact region.

16. The method of claim 15, wherein etching through the mask comprises:
applying a first etch process that stops on the upper etch stop layer;
applying a second etch process that breaks through the upper etch stop layer; and
applying a third etch process, wherein the third etch process stops on or in the semiconductor body in the first opening and stops on the lower etch stop layer in the second opening.

17. The method of claim 15, further comprising, after forming the mesa and the first contact region, growing an epitaxial layer of semiconductor over the front side, wherein the first hole extends through the epitaxial layer.

18. The method of claim 15, wherein pattering the lower etch stop layer leaves a portion of the lower etch stop layer within a spacer-like structure around the mesa.

19. The method of claim 15, further comprising:
forming a second mask over the interlevel dielectric layer, wherein the second mask has a third opening over the mesa;
etching through the second mask, wherein etching forms a second hole corresponding to the third opening; and
depositing more metal, wherein the more metal fills the second hole to form a second electrode contact plug, wherein the second electrode contact plug is coupled through the mesa to a second electrode of the p-n junction.

20. The method of claim 15, further comprising, doping second areas of the semiconductor body to form a second contact region having an opposite doping type from the first contact region, wherein the mask has a third opening and etching through the mask forms a second hole corresponding to the third opening, and depositing metal forms a second electrode contact plug in the second hole, and the second electrode contact plug couples to the second contact region.
